(19) United States
(12) Patent Application Publication
(10) Pub. No.: US 2016/0343766 A1
(43) Pub. Date: Nov. 24, 2016

(54) SOLID-STATE IMAGING DEVICE AND METHOD OF MANUFACTURING SOLID-STATE IMAGING DEVICE

(71) Applicant: KABUSHIKI KAISHA TOSHIBA, Tokyo (JP)

(72) Inventor: Koichi KOKUBUN, Yokohama Kanagawa (JP)

(73) Assignee: KABUSHIKI KAISHA TOSHIBA, Tokyo (JP)

(21) Appl. No.: 14/820,956

(22) Filed: Aug. 7, 2015

(30) Foreign Application Priority Data
May 19, 2015 (JP) 2015-101606

(51) Int. Cl. H01L 27/146; H04N 5/374

(52) U.S. Cl. CPC H01L 27/14643; H04N 5/374; H01L 27/14621; H01L 27/1462; H01L 27/14685

(57) ABSTRACT

According to one embodiment, a solid-state imaging device includes photoelectric conversion elements, filters, and an absorption layer. The filters are each configured to transmit an electromagnetic wave having a predetermined wavelength and to reflect electromagnetic waves having other wavelengths. The filters have flat shapes inclined with respect to a substrate surface and are respectively disposed above the photoelectric conversion elements. The absorption layer is arranged at outer peripheries of arrangement regions of pixels, and at a position closer to a light-receiving face side than arrangement positions of the filters. The absorption layer is made of a material that absorbs electromagnetic waves reflected by the filters. The filters respectively have inclination angles with respect to the substrate surface, which are different from each other in accordance with the types of the pixels.

### CROSS-REFERENCE TO RELATED APPLICATIONS

This application is based upon and claims the benefit of priority from Japanese Patent Application No. 2015-101606, filed on May 19, 2015; the entire contents of which are incorporated herein by reference.

### FIELD

Embodiments described herein relate generally to a solid-state imaging device and a method of manufacturing a solid-state imaging device.

### BACKGROUND

As an image sensor in recent years, there is proposed not only an image sensor of an ordinary RGB type, but also an image sensor of a hyper-spectrum type using multiple wavelengths. As a method of separating electromagnetic waves received by a hyper-spectrum image sensor into multiple wavelengths, there is a method using an interference filter. For example, the interference filter has a structure prepared such that films of two kinds different in refractive index are stacked each to a plurality of layers, and their film thicknesses are set different from each other, to perform separation into the multiple wavelengths. Accordingly, when the interference filters are used as color filters, the film thicknesses of the interference filters to be arranged on respective pixels are adjusted so that the respective pixels can receive light having different wavelengths.

However, in the case of such a structure in which the interference filters of respective pixels are different in film thickness, the respective pixels are provided with different focal distances. Consequently, the resolution for respective wavelengths may be deteriorated. Further, in the case of a structure in which the interference filters on respective pixels are different in inclination angle, light reflected by the interference filters may become stray light and intrude into nearby pixels.

### BRIEF DESCRIPTION OF THE DRAWINGS

FIGS. 1A and 1B are views showing an example of the structure of a solid-state imaging device according to a first embodiment;

FIG. 2 is a view showing an example of spectral characteristics of a dielectric multilayer film of TiO₂/SiO₂;

FIGS. 3A to 3H are sectional views schematically showing an example of the sequence of a method of manufacturing the solid-state imaging device according to the first embodiment;

FIG. 4 is a sectional view schematically showing an example of the structure of a solid-state imaging device according to a second embodiment;

FIGS. 5A to 5C are sectional views schematically showing an example of the sequence of a method of manufacturing the solid-state imaging device according to the second embodiment; and

FIG. 6 is a top view schematically showing an example of the structure of a solid-state imaging device according to a third embodiment.

### DETAILED DESCRIPTION

In general according to one embodiment, a solid-state imaging device including pixels of a plurality of types that are arranged in a two-dimensional state on a substrate and are configured to detect electromagnetic waves having different wavelengths respectively. The solid-state imaging device includes photoelectric conversion elements, filters, and an absorption layer. The photoelectric conversion elements are arranged on the substrate respectively in arrangement regions of the pixels. The filters are each configured to transmit an electromagnetic wave having a predetermined wavelength and to reflect electromagnetic waves having other wavelengths. The filters have flat shapes inclined with respect to a substrate surface and are respectively disposed above the photoelectric conversion elements. The absorption layer is arranged at outer peripheries of arrangement regions of the pixels, and at a position closer to a light-receiving face side than arrangement positions of the filters. The absorption layer is made of a material that absorbs electromagnetic waves reflected by the filters. The filters respectively have inclination angles with respect to the substrate surface, which are different from each other in accordance with the types of the pixels.

Exemplary embodiments of a solid-state imaging device and a method of manufacturing a solid-state imaging device will be explained below in detail with reference to the accompanying drawings. The present invention is not limited to the following embodiments. The sectional views of a solid-state imaging device used in the following embodiments are schematic, and so the relationship between the thickness and width of each layer and/or the thickness ratios between respective layers may be different from actual states.

### First Embodiment

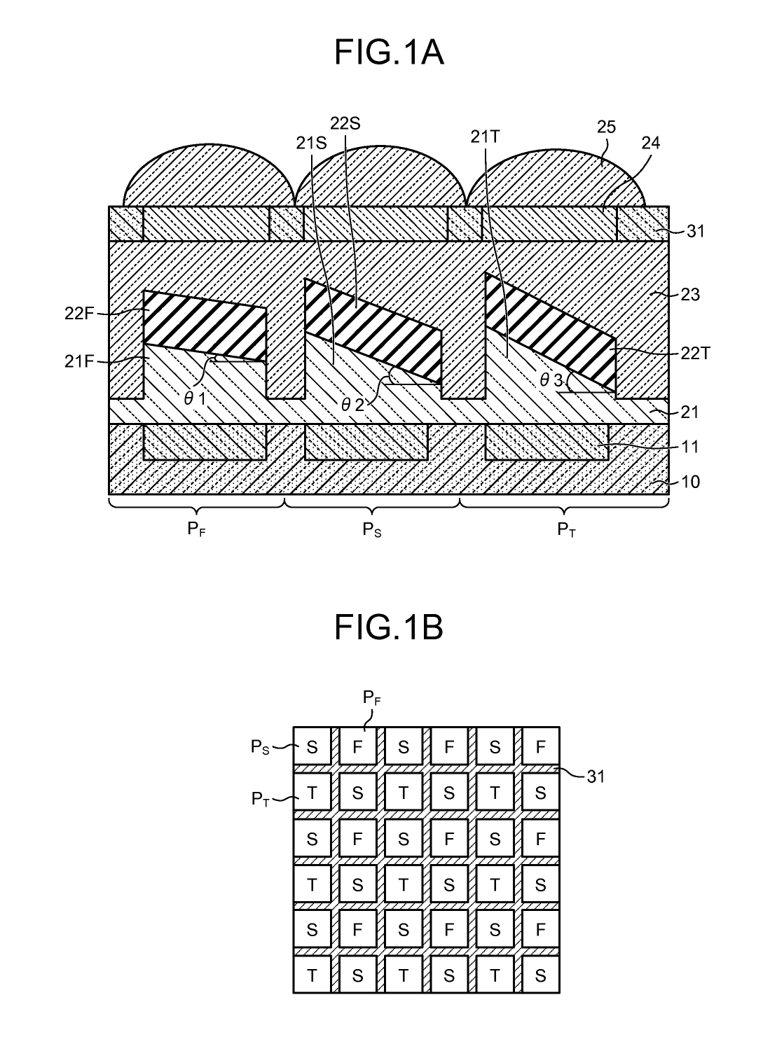

FIGS. 1A and 1B are views showing an example of the structure of a solid-state imaging device according to a first embodiment, FIG. 1A is a sectional view, and FIG. 1B is a top view. Here, in FIG. 1B, illustration of micro-lenses is omitted. The solid-state imaging device includes pixels for detecting electromagnetic waves, which are arranged in a two-dimensional state in accordance with a predetermined rule. The solid-state imaging device is formed with pixels of two types or more. The pixel types are categorized in association with the wavelengths of electromagnetic waves to be detected. The following explanation will be exemplified by a case where the solid-state imaging device includes pixels of three types, i.e., first pixels P_{F}, second pixels P_{S}, and third pixels P_{T}. It should be noted here that electromagnetic waves to be detected by the pixels may be not only light within the visible light region but also electromagnetic waves within the infrared region, the ultraviolet region, and/or another region.

As shown in FIG. 1A, the respective pixels P_{F}, P_{S}, and P_{T} are formed on a semiconductor substrate 10. Each of the pixels P_{F}, P_{S}, and P_{T} has a structure in which a transparent insulating film 21, a multilayer interference filter 22F, 22S, or 22T, a planarization film 23, a transparent insulating film 24, and a micro-lens 25 are stacked on the semiconductor substrate 10 provided with a photoelectric conversion part 11.

The semiconductor substrate 10 may be formed of, e.g., a single-crystalline silicon substrate containing an impurity of a first conductivity type (for example, P-type). The photoelectric conversion part 11 may be exemplified by a photo diode having a pn junction. The photo diodes may be formed by providing semiconductor regions containing an impurity of a second conductivity type (for example, N-type) in the semiconductor substrate 10 of the first conductivity type within the respective arrangement regions of the pixels P_{F}, P_{S}, and P_{T}. Further, although not shown, the semiconductor substrate 10 is also provided with elements, such as an element for reading charges photoelectrically converted by the photoelectric conversion parts 11 of the respective pixels P_{F}, P_{S}, and P_{T}.

The transparent insulating film 21 is arranged on the semiconductor substrate 10. Further, the transparent insulating film 21 is provided with pedestal portions 21F, 21S, and 21T, at which the thickness above the photoelectric conversion parts 11 is larger than the thickness of the other regions not corresponding to the photoelectric conversion parts 11. The upper surface of each of the pedestal portions 21F, 21S, and 21T is flat, but is inclined with respect to the substrate surface by a predetermined angle. The inclination angle is set, in accordance with the type of the pixels P_{F}, P_{S}, and P_{T}, such that the first pixel P_{F} has an inclination angle of θ1, the second pixel P_{S} has an inclination angle of θ2, and the third pixel P_{T} has an inclination angle of θ3. Here, these inclination angles are set to satisfy θ1<θ2<θ3. These inclination angles are respectively equal to the incident angles of electromagnetic waves to the multilayer interference filters 22F, 22S, and 22T, as described later. It suffices if the transparent insulating film 21 is transparent to electromagnetic waves having wavelengths to be detected by the pixels P_{F}, P_{S}, and P_{T}. In this example, the transparent insulating film 21 is formed of a silicon oxide film.

Each of the multilayer interference filters 22F, 22S, and 22T has a function of transmitting an electromagnetic wave having a predetermined wavelength, among the electromagnetic waves having a plurality of wavelengths, and reflecting electromagnetic waves having the other wavelengths. For example, each of the multilayer interference filters 22F, 22S, and 22T is formed of a dielectric multilayer film in which a first insulating film having a first refractive index and a second insulating film having a second refractive index lower than the first refractive index are alternately stacked each in a plurality of layers. For example, the first insulating film may be formed of a TiO₂ film having a refractive index of 2 or more, and the second insulating film may be formed of an SiO₂ film having a refractive index of 1.5 or less. The following explanation will be exemplified by a case where each of the multilayer interference filters 22F, 22S, and 22T is formed of a multilayer film of TiO₂/SiO₂.

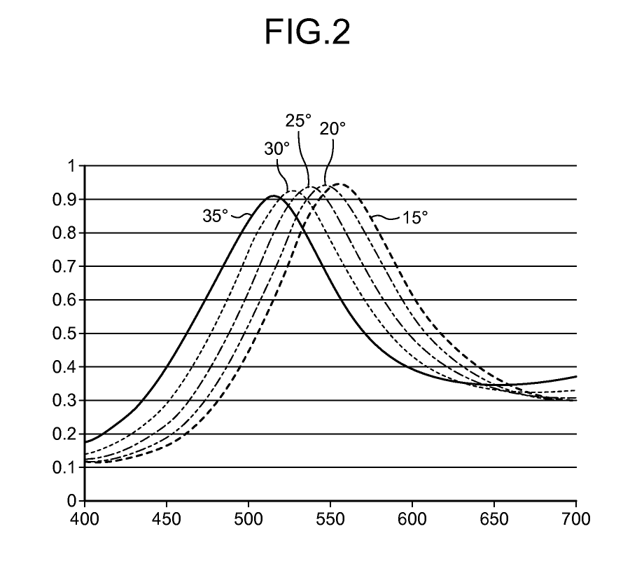

FIG. 2 is a view showing an example of spectral characteristics of a dielectric multilayer film of TiO₂/SiO₂. In FIG. 2, the horizontal axis denotes the wavelength [nm], and the vertical axis denotes the transmittance. FIG. 2 shows changes in the transmittance of the dielectric multilayer film when the light incident angle with respect to the same dielectric multilayer film is changed within a range of from 15° to 35°. As shown in FIG. 2, when the incident angle is 15°, the transmittance becomes maximum at a wavelength of about 560 nm. With an increase in the incident angle, the wavelength for maximizing the transmittance gradually shifts toward the shorter wavelength side. When the incident angle is 35°, that wavelength is about 520 nm.

As described above, in the case of the dielectric multilayer film of TiO₂/SiO₂, even if the same structure is used, the wavelength of light to be transmitted can be shifted by changing the light incident angle. This is also true in general for the multilayer interference filters 22F, 22S, and 22T formed by alternately stacking a plurality of insulating films of different kinds. In light of this, according to the first embodiment, the inclination angles of the multilayer interference filters 22F, 22S, and 22T with respect to the substrate surface are set different from each other depending on the type of the pixels P_{F}, P_{S}, and P_{T}. In this embodiment, the inclination angles of the upper surfaces of the respective pedestal portions 21F, 21S, and 21T are set different from each other, and thus the multilayer interference filters 22F, 22S, and 22T respectively have different angles with respect to the substrate surface. Consequently, even where a dielectric multilayer film of one type is used for the multilayer interference filters in the solid-state imaging device, the transmittable wavelengths to the pixels can be set different from each other. Here, in this example, all of the multilayer interference filters 22F, 22S, and 22T are inclined with respect to the substrate surface, but one of the multilayer interference filters 22F, 22S, and 22T may be formed without being inclined with respect to the substrate surface.

The multilayer interference filters 22F, 22S, and 22T are respectively arranged on the pedestal portions 21F, 21S, and 21T of the transparent insulating film 21, such that the heights at the center of the planes of the multilayer interference filters 22F, 22S, and 22T are almost constant among the respective pixels P_{F}, P_{S}, and P_{T}. Here, in this example, the multilayer interference filters 22F, 22S, and 22T are not present at the regions where the photoelectric conversion parts 11 are not arranged.

The planarization film 23 is formed of an insulating film that is provided to cover the upper sides of the multilayer interference filters 22F, 22S, and 22T and is planarized on the upper surface (light-receiving face) side. It suffices if the planarization film 23 is transparent to electromagnetic waves having wavelengths to be detected by the pixels P_{F}, P_{S}, and P_{T}. In this example, the planarization film 23 may be made from an organic material, such as polysilazane, or may be made from an inorganic material, such as a silicon oxide film.

Each of the transparent insulating films 24 is formed of an insulating film provided between the planarization film 23 and the corresponding micro-lens 25. It suffices if the transparent insulating film 24 is transparent to electromagnetic waves having wavelengths to be detected by the pixels P_{F}, P_{S}, and P_{T}. In this example, the transparent insulating film 24 may be made from an organic material, such as polysilazane, or may be made from an inorganic material, such as a silicon oxide film. The micro-lenses 25 are provided on the transparent insulating film 24 to condense light into the pixels P_{F}, P_{S}, and P_{T}, respectively.

Further, in the solid-state imaging device according to the first embodiment, an absorption layer 31 is provided between adjacent pixels P_{F}, P_{S}, and P_{T} on the upper surface side of the planarization film 23. The absorption layer 31 is arranged at positions to absorb electromagnetic waves reflected by the multilayer interference filters 22F, 22S, and 22T. In the first embodiment, as shown in FIG. 1B, the absorption layer 31 is arranged at the boundary between a pixel P_{F}, P_{S}, or P_{T} and a pixel P_{F}, P_{S}, or P_{T}, i.e., at the outer periphery of each of the pixels P_{F}, P_{S}, and P_{T}. The position where the absorption layer 31 is provided in a direction perpendicular to the substrate surface is determined in accordance with the positions of the multilayer interference filters 22F, 22S, and 22T along with reflection angles estimated from incident light angles. Since there are a plurality of types of pixels P_{F}, P_{S}, and P_{T}, the thickness of the planarization film 23 is determined such that the absorption layer 31 can absorb the reflected light from the multilayer interference filters 22F, 22S, and 22T, which passes through a position closest to the upper surface of the semiconductor substrate 10.

In a case where the wavelengths of reflected electromagnetic waves fall within the visible light region, the absorption layer 31 may be made of an organic material, such as an organic pigment, or an Si-based or Ge-based material, such as poly-silicon, amorphous silicon, or poly-silicon germanium.

As shown in FIG. 1B, the pixels P_{F}, P_{S}, and P_{T} are arranged on the semiconductor substrate 10 to form a Bayer array, for example. According to the Bayer array, 2×2=4 pixels are used as a unit picture element, and are periodically arranged in a two-dimensional state. In FIG. 1B, a unit picture element is composed of one first pixel P_{F}, two second pixels P_{S}, and one third pixel P_{T}. However, this is a mere example, and another type arrangement may be adopted. Further, in the Bayer array shown in FIG. 1B, a first pixel P_{F}, a second pixel P_{S}, and a third pixel P_{T} are not arrayed on a straight line, but FIG. 1A, illustrates the respective pixels P_{F}, P_{S}, and P_{T} as on the same cross section, for the sake of convenience in explanation.

Next, an explanation will be given of an outline of an operation of the solid-state imaging device having the structure described above. Light incident from the micro-lenses 25 reaches the multilayer interference filters 22F, 22S, and 22T of the respective pixels P_{F}, P_{S}, and P_{T}. In each of the multilayer interference filters 22F, 22S, and 22T, the thicknesses of the first insulating film and the second insulating film, and the inclination angle with respect to the substrate surface, serve to determine wavelengths with which light is transmitted, and the other wavelengths with which light is reflected. In other words, the first pixel P_{F} selects light having a first wavelength, the second pixel P_{S} selects light having a second wavelength, and the third pixel P_{T} selects light having a third wavelength. The light thus selected is incident onto the photoelectric conversion part 11 of each of the pixels P_{F}, P_{S}, and P_{T}, and is photoelectrically converted, by which a carrier is accumulated as a signal charge. The signal charge accumulation is controlled by an element for reading (not shown) and is read by a peripheral circuit (not shown).

Further, light reflected by the multilayer interference filters 22F, 22S, and 22T goes through the planarization film 23, and is absorbed by the absorption layer 31. The absorption layer 31 prevents the reflected light from being stray light and intruding into the other pixels P_{F}, P_{S}, and P_{T}. As a result, it is possible to reduce occurrence of sensing malfunction, and deterioration in image quality.

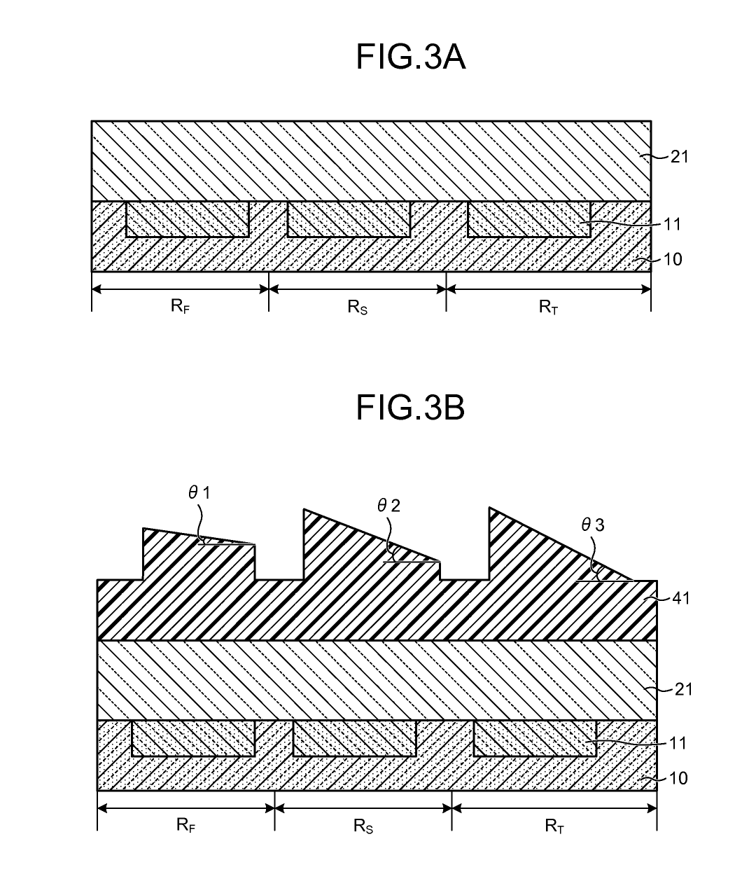

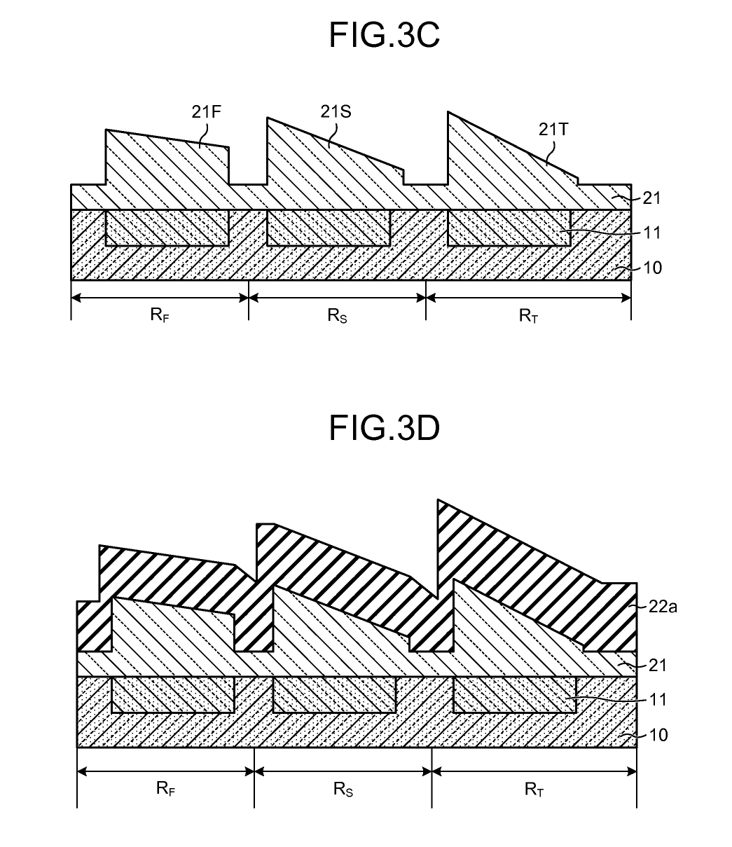

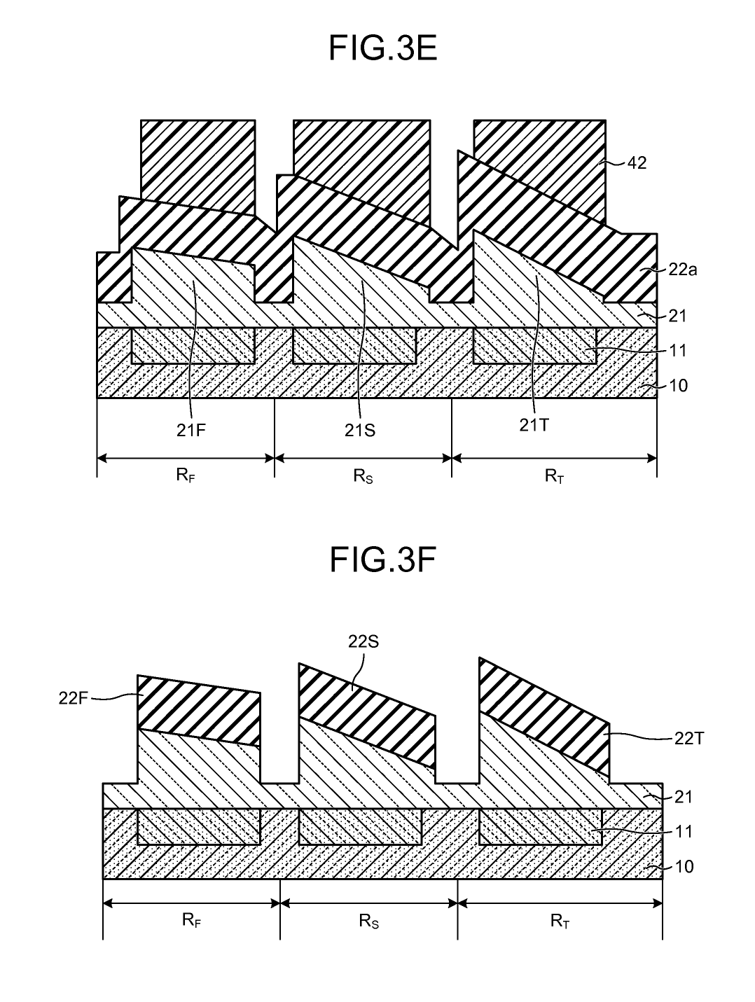

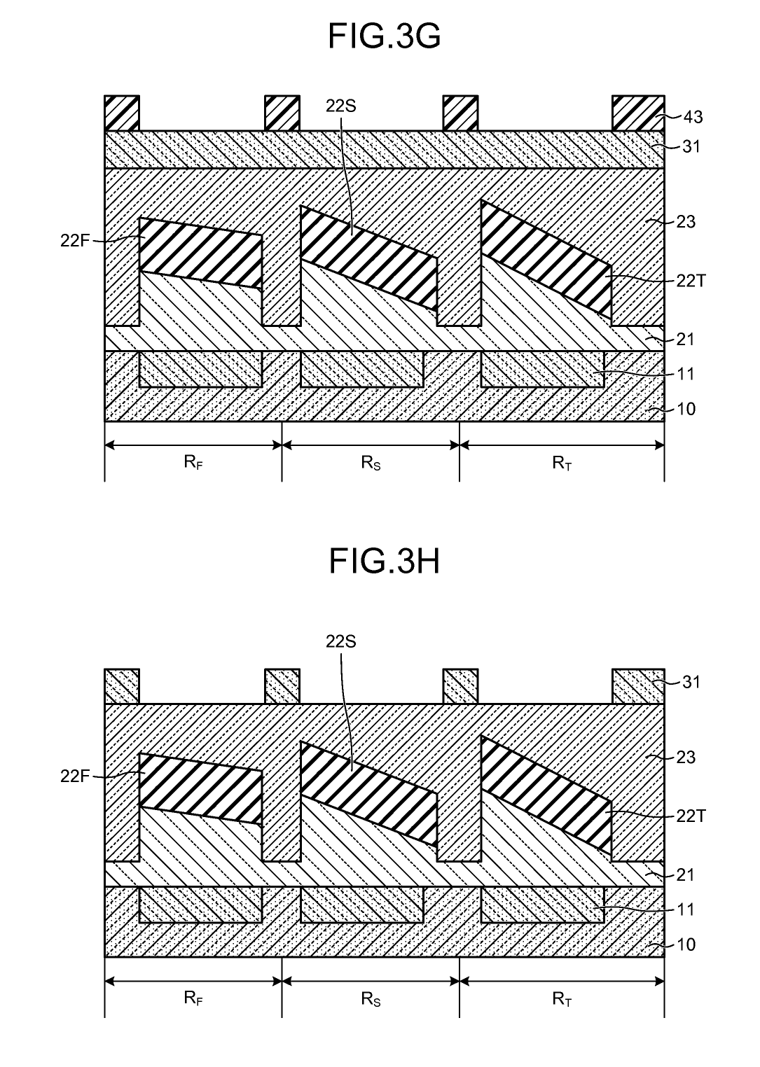

Next, an explanation will be given of a method of manufacturing the solid-state imaging device having the structure described above. FIGS. 3A to 3H are sectional views schematically showing an example of the sequence of a method of manufacturing the solid-state imaging device according to the first embodiment.

At first, as shown in FIG. 3A, photoelectric conversion parts 11 are respectively formed in pixel arrangement regions R_{F}, R_{S}, and R_{T} on a semiconductor substrate 10. The semiconductor substrate 10 may be formed of, e.g., a single-crystalline silicon substrate containing an impurity of a first conductivity type (for example, P-type). In the semiconductor substrate 10 of the first conductivity type, semiconductor regions containing an impurity of a second conductivity type (for example, N-type) are formed by use of an ion implantation method or the like. The semiconductor regions containing an impurity of the second conductivity type are respectively formed in the pixel arrangement regions R_{F}, R_{S}, and R_{T}. Consequently, a photo diode having a pn junction is formed as the photoelectric conversion part 11 in each of the pixel arrangement regions R_{F}, R_{S}, and R_{T}. The pixel arrangement regions R_{F}, R_{S}, and R_{T} are arranged on the semiconductor substrate in, e.g., a Bayer array shown in FIG. 1B, as described above. Further, at this time, although not shown, elements, such as transistors for transferring and/or amplifying charges photoelectrically converted by the photoelectric conversion parts 11, are formed on the semiconductor substrate 10.

Then, a transparent insulating film 21 is formed on the semiconductor substrate 10. Here, as the transparent insulating film 21, a silicon oxide film is formed by a film formation method, such as CVD (Chemical Vapor Deposition) method. The transparent insulating film 21 serves as a substructure for multilayer interference filters 22F, 22S, and 22T.

Thereafter, as shown in FIG. 3B, a resist is applied onto the transparent insulating film 21, and a resist pattern 41 is formed by a lithography process and a development process such that its upper surface has shapes respectively inclined by predetermined angles in the pixel arrangement regions R_{F}, R_{S}, and R_{T}. A pattern having such an inclined shape on the upper surface can be formed by use of a grating dot mask. The grating dot mask is a mask having a distribution of light exposure amount adjusted to be in an inclined shape. Further, if the grating dot mask is used, patterns having inclined shapes on the upper surface, which are of a plurality of types (three types, in this example) different in inclination angle, can be formed together by performing a lithography process once. For example, the first pixel arrangement region R_{F} is provided with a pattern having an inclination angle of θ1, the second pixel arrangement region R_{S} is provided with a pattern having an inclination angle of θ2, and the third pixel arrangement region R_{T} is provided with a pattern having an inclination angle of θ3.

Thereafter, as shown in FIG. 3C, the transparent insulating film 21 is etched, through the resist pattern 41 serving as a mask, by use of anisotropic etching, such as an RIE (Reactive Ion Etching) method. Consequently, the patterns formed on the resist pattern 41 are transferred onto the transparent insulating film 21. Specifically, the first pixel arrangement region R_{F} is provided with a pedestal portion 21F whose upper surface has the inclination angle of θ1, the second pixel arrangement region R_{S} is provided with a pedestal portion 21S whose upper surface has the inclination angle of θ2, and the third pixel arrangement region R_{T} is provided with a pedestal portion 21T whose upper surface has the inclination angle of θ3.

Then, as shown in FIG. 3D, a dielectric multilayer film 22a is formed on the entire surface of the transparent insulating film 21. For example, the dielectric multilayer film 22a is formed by repeatedly and alternately forming a film of TiO₂, which is a material having a higher refractive index, and a film of SiO₂, which is a material having a lower refractive index. At this time, the dielectric multilayer film 22a is formed in a conformal state on the underlying transparent insulating film 21. As a result, the part of the dielectric multilayer film 22a in the first pixel arrangement region R_{F} comes to have the inclination angle of θ1, the part of the dielectric multilayer film 22a in the second pixel arrangement region R_{S} comes to have the inclination angle of θ2, and the part of the dielectric multilayer film 22a in the third pixel arrangement region R_{T} comes to have the inclination angle of θ3.

Thereafter, as shown in FIG. 3E, a resist is applied onto the dielectric multilayer film 22a. Then, patterning is performed by use of a lithography process and a development process to mask the formation regions of the pedestal portions 21F, 21S, and 21T in the respective pixel arrangement regions R_{F}, R_{S}, and R_{T}, and a resist pattern 42 is thereby formed.

Then, as shown in FIG. 3F, the dielectric multilayer film 22a is etched, through the resist pattern 42 serving as a mask, by use of anisotropic etching, such as an RIE method. Consequently, those parts of the dielectric multilayer film 22a in the respective pixel arrangement regions R_{F}, R_{S}, and R_{T} are left on the pedestal portions 21F, 21S, and 21T, and respectively become the multilayer interference filters 22F, 22S, and 22T, which are inclined with respect to the substrate surface.

Thereafter, as shown in FIG. 3G, a planarization film 23 is formed on the transparent insulating film 21 provided with the multilayer interference filters 22F, 22S, and 22T. The planarization film 23 may be formed by applying an organic material, or may be formed by forming an inorganic material and then planarizing its upper surface by use of a CMP (Chemical Mechanical Polishing) method. In a case where the photoelectric conversion parts 11 are used to detect electromagnetic waves within the visible light region, the planarization film 23 may be made from polysilazane or a silicon oxide film, for example.

Further, an absorption layer 31 is formed on the entire surface of the planarization film 23. In a case where the photoelectric conversion parts 11 are used to detect electromagnetic waves within the visible light region, the absorption layer 31 may be made of an organic pigment, poly-silicon, amorphous silicon, or poly-silicon germanium.

Further, a resist is applied onto the entire surface of the absorption layer 31. Then, a resist pattern 43 is formed by use of a lithography process and a development process, such that openings are respectively formed at the pixel arrangement regions R_{F}, R_{S}, and R_{T}, i.e., a pattern is left at the boundary between the pixels P_{F}, P_{S}, and P_{T}.

Then, as shown in FIG. 3H, the absorption layer 31 is etched, through the resist pattern 43 serving as a mask, by use of anisotropic etching, such as an RIE method. Here, a thickness of the planarization film 23, at the position where the absorption layer 31 is formed, is set to a thickness with which the reflected light from the multilayer interference filters 22F, 22S, and 22T can be incident onto the absorption layer 31.

Thereafter, a transparent insulating film 24 is formed on the planarization film 23 provided with the absorption layer 31. Then, the part of the transparent insulating film 24 present above the upper surface of the absorption layer 31 is removed by a CMP method or the like. Then, micro-lenses 25 are respectively formed on the pixel arrangement regions R_{F}, R_{S}, and R_{T}. As a result, the solid-state imaging device shown in FIGS. 1A and 1B is obtained.

According to the first embodiment, the pixels P_{F}, P_{S}, and P_{T} of a plurality of types are arranged on the semiconductor substrate 10, such that they respectively include the multilayer interference filters 22F, 22S, and 22T inclined by different angles with respect to the substrate surface. Further, the absorption layer 31 is provided on the planarization film 23 covering the multilayer interference filters 22F, 22S, and 22T, at the boundary between the adjacent pixels P_{F}, P_{S}, and P_{T}, so that the absorption layer 31 can absorb electromagnetic waves reflected by the multilayer interference filters 22F, 22S, and 22T. Consequently, incident electromagnetic waves can be separated by the respective pixels P_{F}, P_{S}, and P_{T} with high resolution. Further, since electromagnetic waves reflected by the multilayer interference filters 22F, 22S, and 22T are absorbed by the absorption layer 31, stray light due to the reflected electromagnetic waves is reduced. As a result, it is possible to detect electromagnetic waves having predetermined wavelengths by the respective pixels P_{F}, P_{S}, and P_{T} with high accuracy. Further, it is possible to separate different wavelengths by the respective pixels P_{F}, P_{S}, and P_{T}, while using the multilayer interference filters 22F, 22S, and 22T made from the same materials in the plurality of pixels P_{F}, P_{S}, and P_{T}.

Further, since the heights at the center of the planes of the multilayer interference filters 22F, 22S, and 22T are set almost constant among the respective pixels P_{F}, P_{S}, and P_{T}, the light focal distances are made uniform among the respective pixels P_{F}, P_{S}, and P_{T}. As a result, the spectral resolution for multiple wavelengths is prevented from being deteriorated.

Further, the transparent insulating film 21, whose upper surface is provided with parts having different inclination angles at the respective pixel arrangement regions R_{F}, R_{S}, and R_{T}, can be formed by performing a lithography process and an etching process each once. Accordingly, the number of lithography processes and etching processes can be reduced, as compared with a case where the processes are performed to each group of the pixel arrangement regions having the same inclination angle. As a result, it is possible to reduce the process cost.

### Second Embodiment

In the first embodiment, an explanation has been given of a case where the absorption layer is arranged on the planarization film. In the second embodiment, an explanation will be given of a case where the absorption layer is partly embedded in the planarization film.

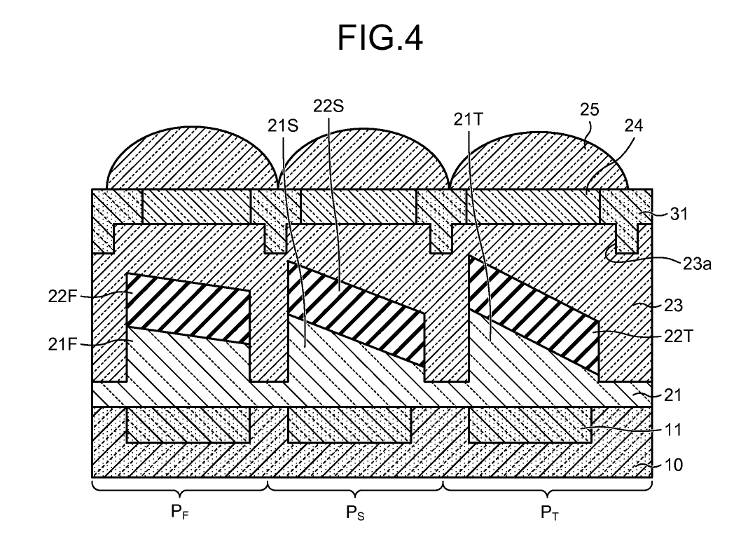

FIG. 4 is a sectional view schematically showing an example of the structure of a solid-state imaging device according to the second embodiment. In the solid-state imaging device according to the second embodiment, a trench 23a is formed at the boundary between the pixels and extends in the planarization film 23 from its upper surface to a predetermined depth, and the absorption layer 31 is formed in this trench 23a and on the planarization film 23 outside the trench 23a. In this way, since the absorption layer 31 includes a lower end positioned closer to the semiconductor substrate 10, the absorption layer 31 can absorb more electromagnetic waves reflected by the multilayer interference filters 22F, 22S, and 22T. Here, the constituent elements corresponding to those described in the first embodiment are denoted by the same reference symbols, and their description is omitted.

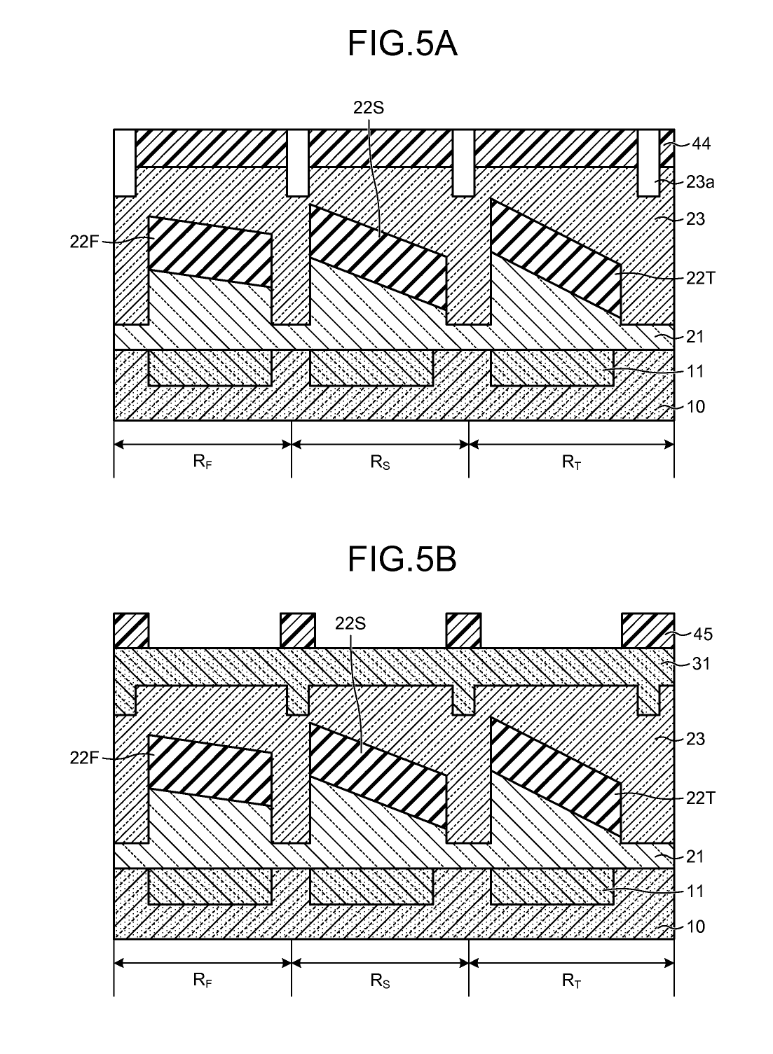

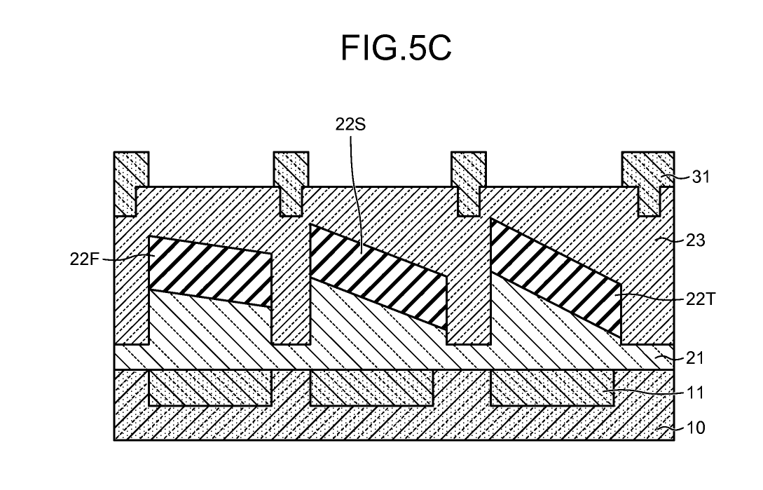

Next, an explanation will be given of a method of manufacturing this solid-state imaging device. FIG. 5A to FIG. 5C are sectional views schematically showing an example of the sequence of a method of manufacturing the solid-state imaging device according to the second embodiment. Here, this method is the same as that of the first embodiment up to a halfway part shown in FIG. 3F, and so their description is omitted and only different parts will be described.

As shown in FIG. 5A, a planarization film 23 is formed on the transparent insulating film 21 provided with the multilayer interference filters 22F, 22S, and 22T, and a resist is further applied onto the entire surface of the planarization film 23. Then, a resist pattern 44 is formed by use of a lithography process and a development process, such that an opening is formed at the outer periphery of each of the pixels P_{F}, P_{S}, and P_{T}, i.e., at the boundary between the pixels P_{F}, P_{S}, and P_{T}.

Then, the planarization film 23 is etched to a predetermined depth, through the resist pattern 44 serving as a mask, by use of anisotropic etching, such as an RIE method. Consequently, a trench 23a having the predetermined depth is formed in the planarization film 23 at the boundary between the pixels P_{F}, P_{S}, and P_{T}.

The resist pattern 44 is removed, and then, as shown in FIG. 5B, an absorption layer 31 is formed on the planarization film 23 provided with the trench 23a. The absorption layer 31 is formed such that it fills the trench 23a and has a predetermined thickness on the planarization film 23. The material of the absorption layer 31 used here is the same as that explained in the first embodiment.

Further, a resist is applied onto the entire surface of the absorption layer 31. Then, a resist pattern 45 is formed by use of a lithography process and a development process, such that openings are respectively formed at the pixel arrangement regions R_{F}, R_{S}, and R_{T}, i.e., a pattern is left at the boundary between the pixels P_{F}, P_{S}, and P_{T}. At this time, the patterning is performed such that the width of the resist pattern 45 on the planarization film 23 is larger than the width of the trench 23a, in a cross section perpendicular to the extending direction of the trench 23a.

Then, as shown in FIG. 5C, the part of the absorption layer 31 present above the planarization film 23 is etched, through the resist pattern 45 serving as a mask, by use of anisotropic etching, such as an RIE method.

Thereafter, a transparent insulating film 24 is formed on the planarization film 23 provided with the absorption layer 31. Then, the part of the transparent insulating film 24 present above the upper surface of the absorption layer 31 is removed by a CMP method or the like. Then, micro-lenses 25 are respectively formed on the pixel arrangement regions R_{F}, R_{S}, and R_{T}. As a result, the solid-state imaging shown in FIG. 4 is obtained.

The second embodiment can provide the same effects as the first embodiment.

### Third Embodiment

In the first and second embodiments, an explanation has been given of a case where the absorption layer is arranged over the entirety of the outer periphery of each pixel. In the third embodiment, an explanation will be given of a case where the absorption layer is arranged at part of the outer periphery of each pixel.

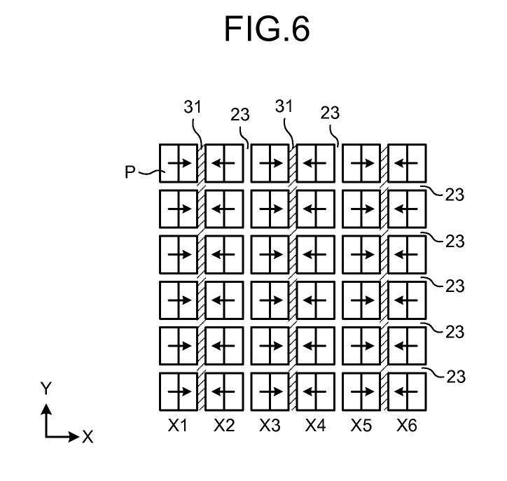

FIG. 6 is a top view schematically showing an example of the structure of a solid-state imaging device according to the third embodiment. Here, in FIG. 6, illustration of micro-lenses is omitted. Further, in FIG. 6, the direction of the intersection line between the inclined surface (for example, the upper surface) of each of the multilayer interference filters 22F, 22S, and 22T and a plane parallel with the substrate surface is defined as a strike, and is indicated by a straight line in each pixel. Further, an arrow shown in a direction perpendicular to this strike denotes the inclined direction of the inclined surface. In other words, each arrow means that the height of the inclined surface is becoming lower in the direction from the starting point to the ending point of the arrow.

In FIG. 6, the pixels P arranged in a column X1, a column X3, a column X5, and so forth are provided with multilayer interference filters 22F, 22S, and 22T, in each of which the inclined surface is formed to have its strike in a Y-direction and to have its height lowered in an X-direction toward the positive side. In each of such multilayer interference filters 22F, 22S, and 22T, electromagnetic waves incident in a Z-direction perpendicular to the X-Y plane are reflected in the X-direction toward the positive side.

Further, the pixels P arranged in a column X2, a column X4, a column X6, and so forth are provided with multilayer interference filters 22F, 22S, and 22T, in each of which the inclined surface is formed to have its strike in the Y-direction and to have its height lowered in the X-direction toward the negative side. In each of such multilayer interference filters 22F, 22S, and 22T, electromagnetic waves incident in the Z-direction perpendicular to the X-Y plane are reflected in the X-direction toward the negative side.

Accordingly, if the absorption layer 31 is arranged at least at the boundary portion between the pixels of the column X1 and the pixels of the column X2, the boundary portion between the pixels of the column X3 and the pixels of the column X4, the boundary portion between the pixels of the column X5 and the pixels of the column X6, and so forth, electromagnetic waves reflected by the respective pixels P can be absorbed. In other words, it is unnecessary to provide the absorption layer 31 at regions where reflected electromagnetic waves do not reach. In the structure shown in FIG. 6, the absorption layer 31 does not include portions corresponding to the boundary portion between the pixels of the column X2 and the pixels of the column X3, the boundary portion between the pixels of the column X4 and the pixels of the column X5, and so forth. Further, the absorption layer 31 does not include portions corresponding to the boundary portions between the pixels P adjacent to each other in the Y-direction. Consequently, the use amount of the absorption layer 31 can be reduced.

FIG. 6 shows a case where pixels P adjacent to each other share a portion of the absorption layer 31, but each pixel P may be provided with a portion of the absorption layer 31 only at a position in the reflection direction of electromagnetic waves so that the use amount of the absorption layer 31 can be reduced. Here, the inclined direction of the inclined surface may be set in an arbitrary direction in each of the multilayer interference filters 22F, 22S, and 22T of the pixels P, and thus the arrangement position of the absorption layer 31 is determined in accordance with the inclined direction of the inclined surface of each of the multilayer interference filters 22F, 22S, and 22T.

A method of manufacturing the solid-state imaging device having the structure described above is basically the same as the sequence explained in the first and second embodiments. However, this method differs in that the inclined direction of each of the pedestal portions 21F, 21S, and 21T of the transparent insulating film 21 varies depending on the position of the corresponding pixel P. Further, this method differs in that the absorption layer 31 is not arranged over the entirety of the outer peripheries of the pixels P but arranged locally at positions in the reflection directions of electromagnetic waves from the multilayer interference filters 22F, 22S, and 22T.

According to the third embodiment, the absorption layer 31 is arranged locally at positions in the reflection directions of electromagnetic waves from the multilayer interference filters 22F, 22S, and 22T. Consequently, the use amount of the absorption layer 31 can be reduced, as compared with a case where the absorption layer 31 is arranged over the entirety of the outer peripheries of the pixels P. As a result, it is possible to reduce the manufacturing cost of the solid-state imaging device, as compared with the first and second embodiments.

What is claimed is:

1. A solid-state imaging device including pixels of a plurality of types that are arranged in a two-dimensional state on a substrate and are configured to detect electromagnetic waves having different wavelengths respectively, the solid-state imaging device comprising:
photoelectric conversion elements arranged on the substrate respectively in arrangement regions of the pixels;
filters each configured to transmit an electromagnetic wave having a predetermined wavelength and to reflect electromagnetic waves having other wavelengths, the filters having flat shapes inclined with respect to a substrate surface and respectively disposed above the photoelectric conversion elements, and
an absorption layer arranged at outer peripheries of arrangement regions of the pixels, and at a position closer to a light-receiving face side than arrangement positions of the filters,
wherein the absorption layer is made of a material that absorbs electromagnetic waves reflected by the filters, and
the filters respectively have inclination angles with respect to the substrate surface, which are different from each other in accordance with the types of the pixels.

2. The solid-state imaging device according to claim 1, wherein, with reference to a surface of the substrate on which the pixels are arranged, positions at a center of planes of the filters are set at almost same position, regardless of the types of the pixels.

3. The solid-state imaging device according to claim 1, further comprising a planarization film arranged on the filters,
wherein the absorption layer is arranged on the planarization film at the outer peripheries of the arrangement regions of the pixels.

4. The solid-state imaging device according to claim 3, wherein the absorption layer is further arranged in the planarization film from a light-receiving face side to a predetermined depth, at the outer peripheries of the arrangement regions of the pixels.

5. The solid-state imaging device according to claim 1, wherein the absorption layer is arranged locally at parts of the outer peripheries of the arrangement regions of the pixels.

6. The solid-state imaging device according to claim 5, wherein the absorption layer is arranged in directions in which incident electromagnetic waves are reflected from the filters, at the outer peripheries of the arrangement regions of the pixels.

7. The solid-state imaging device according to claim 5, wherein, in the pixels adjacent to a portion of the absorption layer, the filters are provided such that reflection directions of incident electromagnetic waves from these filters are in directions in which this portion of the absorption layer is arranged, and
these pixels share this portion of the absorption layer.

8. The solid-state imaging device according to claim 1, wherein the filter is formed of a dielectric multilayer film in which a first insulating film and a second insulating film having a refractive index smaller than the first insulating film are alternately stacked each in a plurality of layers.

9. The solid-state imaging device according to claim 8, wherein the first insulating film is formed of a TiO₂ film, and
the second insulating film is formed of an SiO₂ film.

10. The solid-state imaging device according to claim 1, wherein the absorption layer is made of an organic material or inorganic material.

11. The solid-state imaging device according to claim 1, wherein the absorption layer includes an organic pigment, silicon-based material, or germanium-based material.

12. A method of manufacturing a solid-state imaging device, the method comprising:
forming a first transparent insulating film on a substrate provided with a photoelectric conversion element;
forming a first resist pattern on the first transparent insulating film, the first resist pattern including a pattern having an upper surface inclined with respect to a substrate surface, at a position corresponding to a formation position of the photoelectric conversion element;
etching the first transparent insulating film, through the first resist pattern serving as a mask to form a pedestal portion formed of the first transparent insulating film and having an inclined upper surface;
forming a filter on a pedestal portion;
forming a planarization film above the first transparent insulating film provided with the filter; and
forming an absorption layer on the planarization film, corresponding to an outer periphery of an arrangement position of a pixel.

13. The method of manufacturing a solid-state imaging device according to claim 12, wherein, in the forming of the first resist pattern, the first resist pattern with patterns of a plurality of types is formed corresponding to pixel arrangement regions respectively, the patterns having different inclination angles of upper surfaces with respect to the substrate surface.

14. The method of manufacturing a solid-state imaging device according to claim 12, wherein the forming of the filter includes
forming a filter film on the first transparent insulating film provided with the pedestal portion,
forming a second resist pattern covering the pedestal portion, on the filter film, and
etching the filter film, through the second resist pattern serving as a mask.

15. The method of manufacturing a solid-state imaging device according to claim 12, further comprising:
forming, after the forming of the planarization film and before the forming of the absorption layer, a trench having a predetermined depth in the planarization film at a position corresponding to the outer periphery of the arrangement position of the pixel, wherein,
in the forming of the absorption layer, the absorption layer is formed so as to fill the trench.

16. The method of manufacturing a solid-state imaging device according to claim 15, wherein, in the forming of the absorption layer, the absorption layer is also formed on the planarization film outside the trench, at the outer periphery of the arrangement position of the pixel.

17. The method of manufacturing a solid-state imaging device according to claim 12, wherein in the forming of the absorption layer, the absorption layer is locally formed, corresponding to a part of the outer periphery of the arrangement position of the pixel.

18. The method of manufacturing a solid-state imaging device according to claim 17, wherein, in the forming of the absorption layer, the absorption layer is formed in a direction in which incident electromagnetic waves are reflected from the filter, at the outer periphery of the arrangement position of the pixel.

19. The method of manufacturing a solid-state imaging device according to claim 12, wherein, in the forming of the filter, a dielectric multilayer film in which a first insulating film and a second insulating film having a refractive index smaller than the first insulating film are alternately stacked each in a plurality of layers is formed.

20. The method of manufacturing a solid-state imaging device according to claim 19, wherein the first insulating film is formed of a TiO₂ film, and
the second insulating film is formed of an SiO₂ film.
